(19) United States
(12) Patent Application Publication
(10) Pub. No.: US 2002/0014308 A1
(43) Pub. Date: Feb. 7, 2002

(54) Plasma etching apparatus

(76) Inventor: Takayoshi Sawayama, Miyazaki (JP)

Correspondence Address: JONES VOLENTINE, L.L.P., Suite 150, 12200 Sunrise Vally Drive, Reston, VA, 20191, US

(21) Appl. No.: 09/754,277

(22) Filed: Jan. 5, 2001

(30) Foreign Application Priority Data
Jul. 26, 2000 (JP) 225686/2000

(51) Int. Cl. H01L 21/3065

(52) U.S. Cl. 156/345

(57) ABSTRACT

A problem arose in that when gas holes defined in a gas-introducing plate lying within a plasma etching apparatus reached more than a given size, plasma entered from an etching-processing chamber to the backside (cooling plate side) of a gas-introducing plate through the gas holes.

In order to solve such a problem, there is provided an upper electrode which comprises a cooling plate having a plurality of gas supply holes for supplying gas, a gas-introducing plate having gas holes for introducing the gas into a semiconductor wafer uniformly, a jig for fixing the gas-introducing plate to the cooling plate, and a sensor for detecting plasma.

### BACKGROUND OF THE INVENTION

1. Field of the Invention

The present invention relates to a structure of an apparatus (plasma etching apparatus) for manufacturing a semiconductor device.

2. Description of the Related Art

The interior of a processing chamber in a conventional etching apparatus comprises an upper electrode 6 for supplying gas, and a lower electrode 7 on which a wafer corresponding to an object to be etched is placed. A description will be made of it below with reference to FIG. 1.

The upper electrode 6 comprises a cooling plate 2 provided with gas supply holes 1 defined therein, a gas-introducing plate 4 provided with a plurality of gas holes 3 defined therein, and a jig 5 for fixing the gas-introducing plate 4 to the cooling plate 2. A wafer 8 corresponding to an object to be etched can be placed on the lower electrode 7. Upon actual etching, high-frequency power is supplied between the upper electrode 6 and the lower electrode 7. In doing so, plasma is generated to etch the wafer 8. The etching is carried out within an etching-processing chamber 9.

Now, the gas-introducing plate 4 introduces the gas discharged through the gas supply holes 1 defined in the cooling plate 2 in plural form onto the wafer 8. The gas-introducing plate 4 is a consumable good and has the need for its regular replacement.

When the gas-introducing plate 4 lying within the processing chamber of the etching apparatus is used up, the gas-introducing plate 4 becomes thin as shown in FIG. 5. Further, the gas holes 3 defined in the gas-introducing plate increase in size. When the gas holes 3 of the gas-introducing plate 4 reach a given size or more respectively, the following would occur. Plasma enters the backside (cooling plate side) of the gas-introducing plate from the etching-processing chamber 9 through the enlarged gas holes 3. Designated at numeral 10 in FIG. 5 typically illustrates the entrance of the plasma into the backside of the gas-introducing plate 4. When the plasma enters therein, the state of discharge of the plasma on the wafer side becomes unstable. As a result, an etching characteristic is deteriorated and the wafer 8 is unusually processed.

Further, the occurrence of the plasma in the backside of the gas-introducing plate 4 is not limited to the aforementioned case. The plasma is generated even in a case where pressure in an apparatus varies and a case where the amount of supply of high-frequency power varies, for example.

Further, when a plasma discharge is kept long on the backside of the gas-introducing plate 4, particles are produced depending on reactants. There is a possibility that the wafer will be contaminated with the produced particles.

Accurately recognizing when the gas-introducing plate 4 needs replacing, allows the solution of such a problem as described above.

### SUMMARY OF THE INVENTION

An object of the present invention is to provide an apparatus for manufacturing a semiconductor device, which is capable of accurately recognizing when a gas-introducing plate of an upper electrode needs replacing, and detecting even etching trouble.

According to the present invention, for achieving the above object, an upper electrode of a parallel-plate type dry etching apparatus is configured as follows: Means for detecting plasma is provided inside the upper electrode for supplying gas.

Described more specifically, the upper electrode comprises a cooling plate having a plurality of gas supply holes for supplying the gas, a gas-introducing plate having gas holes for introducing the gas into a semiconductor wafer, a jig for fixing the gas-introducing plate to the cooling plate, and a sensor for detecting plasma. Thus, when the gas holes of the gas-introducing plate increase in size with their wearing and hence the plasma is generated on the backside of the gas-introducing plate, the sensor for detecting the plasma serves. At this point in time, the etching apparatus is deactivated.

In the present invention as well, means for detecting pressure is provided inside an upper electrode for supplying gas, of a parallel-plate type dry etching apparatus.

Described more specifically, the upper electrode comprises a cooling plate having a plurality of gas supply holes for supplying the gas, a gas-introducing plate having gas holes for introducing the gas into a semiconductor wafer, a jig for fixing the gas-introducing plate to the cooling plate, and a sensor for detecting pressure. Thus, when the gas holes of the gas-introducing plate increase in size with their wearing and hence the plasma is generated on the backside of the gas-introducing plate, the pressure sensor detects a reduction in pressure. At this point in time, the etching apparatus stops operating.

Further, in the present invention, first pressure detecting means is provided inside an upper electrode for supplying gas, of a parallel-plate type dry etching apparatus. Second pressure detecting means is provided within an etching-processing chamber in which a wafer is placed.

Described more specifically, the first pressure detecting means and the second pressure detecting means are connected to detect the difference between pressure detected by the first pressure detecting means and pressure detected by the second pressure detecting means. When gas holes of a gas-introducing plate increase in size with their wearing and hence plasma is generated on the backside of the gas-introducing plate, a reduction in the difference between pressure inside the upper electrode and pressure inside the etching-processing chamber is detected. At this point in time, the etching apparatus is stopped.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a diagram showing a cross-section of a conventional semiconductor device manufacturing apparatus in which a gas-introducing plate is less worn;

FIG. 2 is a diagram illustrating a cross-section of a conventional semiconductor device manufacturing apparatus in which a gas-introducing plate increases markedly in wear;

FIG. 3 is a diagram depicting a cross-section of an apparatus for manufacturing a semiconductor device, according to a first embodiment of the present invention;

FIG. 4 is a diagram showing a cross-section of an apparatus for manufacturing a semiconductor device, according to a second embodiment of the present invention; and

FIG. 5 is a diagram illustrating a cross-section of an apparatus for manufacturing a semiconductor device, according to a third embodiment of the present invention.

### DETAILED DESCRIPTION OF THE PREFFERED EMBODIMENTS

Respective embodiments of the present invention will hereinafter be described in detail with reference to the accompanying drawings. In the respective embodiments, the same elements or components are identified by like reference numerals.

(First Embodiment)

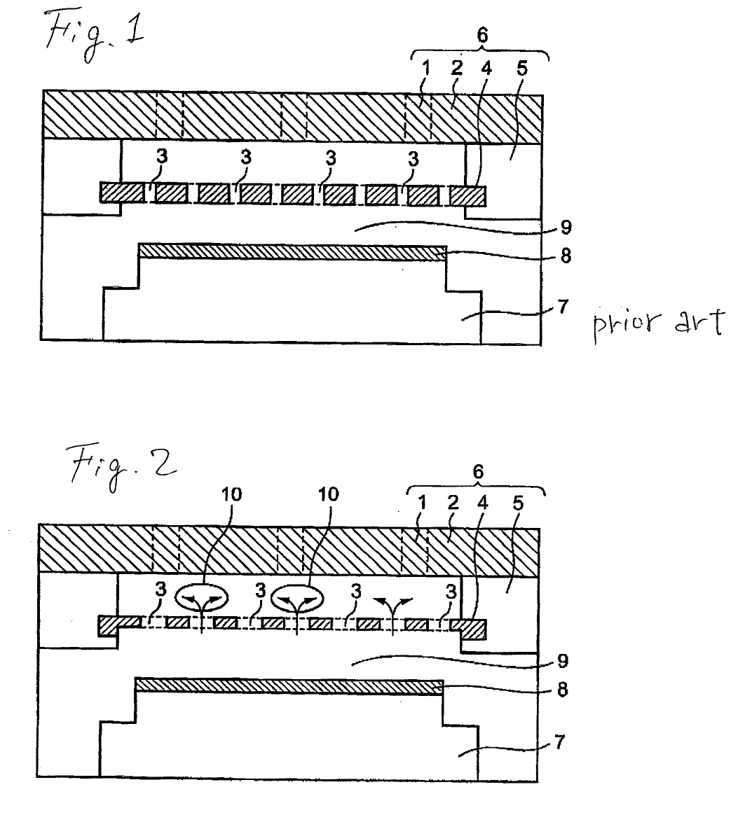

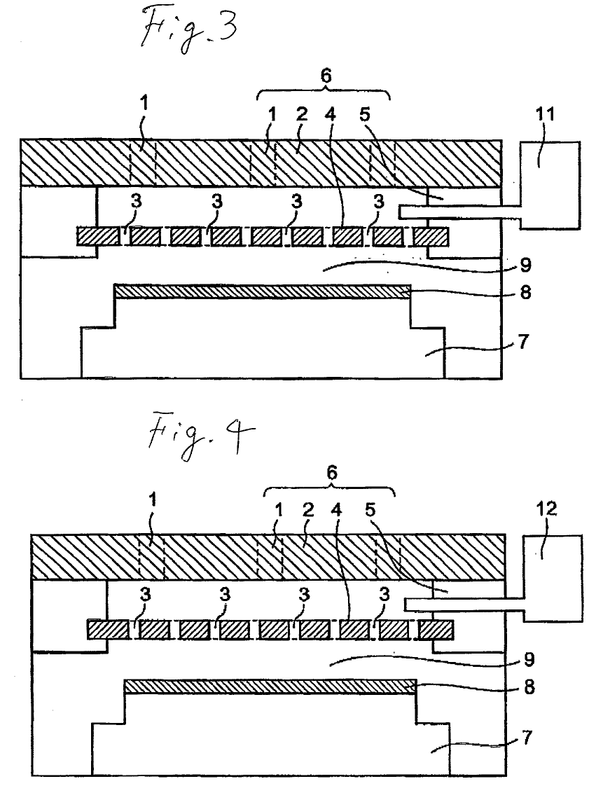

FIG. 1 shows a processing chamber of an etching apparatus according to a first embodiment of the present invention. It is identical in basic configuration to a conventional one. In the conventional etching apparatus, such a device as to detect a plasma was not placed on the backside (on the cooling plate 2 side in FIG. 1) of a gas-introducing plate 4. In the first embodiment, a plasma detector 11 is placed on the backside of the gas-introducing plate 4. A commercially available detector may be used as the plasma detector 11. It is however desirable to use a high-sensitive plasma detector capable of detecting even slight plasma. Further, the plasma detector 11 is placed in a position where it is most easy to detect the plasma.

As shown in FIG. 1, the plasma is stably generated while the normal etching process is being carried out. However, when the etching process is done many times, the gas-introducing plate is also etched. Thus, the thickness of the gas-introducing plate 4 becomes thinner. Further, gas holes 3 defined in the gas-introducing plate increase in size. When the sizes of the gas holes 3 defined in the gas-introducing plate 4 respectively reach more than a predetermined size, the plasma is introduced into the reverse side of the gas-introducing plate 4 through the gas holes 3.

The high-sensitive plasma detector 11 detects the slight plasma introduced into the backside of the gas-introducing plate 4. Next, the etching apparatus is deactivated. Further, the plasma detector 11 notifies the gas-introducing plate to be replaced by another to one.

When gas leaks within an etching-processing chamber 9, pressure varies on the backside of the gas-introducing plate 4. Plasma is generated on the backside of the gas-introducing plate according to such a pressure fluctuation. Even in this case, the generated plasma is detected by the plasma detector. Further, the etching apparatus is brought to a halt. The cause of the leakage of the gas within the etching-processing chamber becomes apparent.

Further, when the amount of supply of high-frequency power varies, abnormal or improper etching is done. At this time, the state of discharge of the plasma becomes unstable. Further, plasma is generated on the backside of the gas-introducing plate. Even in this case, the generated plasma is detected by the plasma detector 11. Then, the etching apparatus is brought to a halt.

In either case referred to above, the slight plasma generated on the backside of the gas-introducing plate 4 is detected by the high-sensitive plasma detector 11. Then, the etching apparatus is deactivated. Afterwards, the etching apparatus is checked. Thus, the cause of a malfunction thereof is removed.

As described above, the high-sensitive plasma detector 11 is placed on the backside of the gas-introducing plate 4. The plasma generated on the reverse side of the gas-introducing plate 4 is detected with high accuracy. The etching apparatus is deactivated simultaneously with the time when defective conditions are detected. Further, the worn-out gas-introducing plate 4 is reliably replaced with another. Thus, a wafer 8 can be prevented from being abnormally etched due to the wearing-out of the gas-introducing plate 4. Further, since the gas-introducing plate 4 can be used up to its limit, it can be reduced in cost.

(Second Embodiment)

FIG. 4 is a diagram showing a second embodiment. In the second embodiment, the plasma detector 11 employed in the first embodiment is replaced by a pressure gauge 12.

Any pressure measuring apparatuses were not conventionally installed on the backside (on the cooling plate 2 side in FIG. 4) of the gas-introducing plate 4. In the present embodiment, the pressure gauge 12 is provided thereat. The pressure gauge 12 may be one now on the market. It is desirable that a high-accuracy pressure gauge capable of capturing a slight fluctuation in pressure is used.

While normal etching is being carried out within an etching-processing chamber 9, no plasma enters the backside of the gas-introducing plate 4. However, when the gas-introducing plate 4 is used up, gas holes 3 defined in the gas-introducing plate 4 increase in size. When the size of each gas hole 3 exceeds a predetermined size, the plasma enters the back of the gas-introducing plate 4. In doing so, a fluctuation in pressure occurs on the backside of the gas-introducing plate.

Even when trouble occurs in the etching-processing chamber and hence the state of the plasma becomes unstable, the plasma is generated on the backside of the gas-introducing plate. As the occurrence of defective conditions, may be mentioned a case in which a fluctuation in pressure due to leaks occurs, a case in which the amount of supply of high-frequency power varies, etc. In a manner similar to the above even in these cases, a pressure fluctuation occurs on the backside of the gas-introducing plate.

While the etching is being carried out in a normal state, the backside (cooling plate 2 side) of the gas-introducing plate 4 is higher than the etching-processing chamber 9 in pressure. This is because gas is always supplied from gas supply holes 1 defined in the cooling plate 2 in plural form on the backside of the gas-introducing plate 4. On the other hand, since the gas reacted by etching is always exhausted from the etching-processing chamber 9, the pressure is relatively low. When the plasma enters the back of the gas-introducing plate 4 or is generated on the backside thereof, the pressure changes and is caused to transition from its high state to its low state. The pressure gauge 12 detects such a change in pressure. When the detected pressure is lower than set pressure, the etching apparatus is deactivated.

Owing to the provision of the high-accuracy pressure gauge 12 on the backside of the gas-introducing plate 4 as described above, the fluctuation in pressure is detected with high accuracy. The etching apparatus is stopped simultaneously with the time when the defective conditions are detected. Thus, the wasted gas-introducing plate is reliably replaced by another.

Thus, a wafer can be prevented form being abnormally etched due to overusing of the gas-introducing plate 4. Since the gas-introducing plate 4 can be used to its limitation, a reduction in cost thereof can be achieved.

Further, since the pressure gauge 12 employed in the present embodiment is cheaper than the plasma detector 11 employed in the first embodiment, a further reduction in cost can be achieved.

(Third Embodiment)

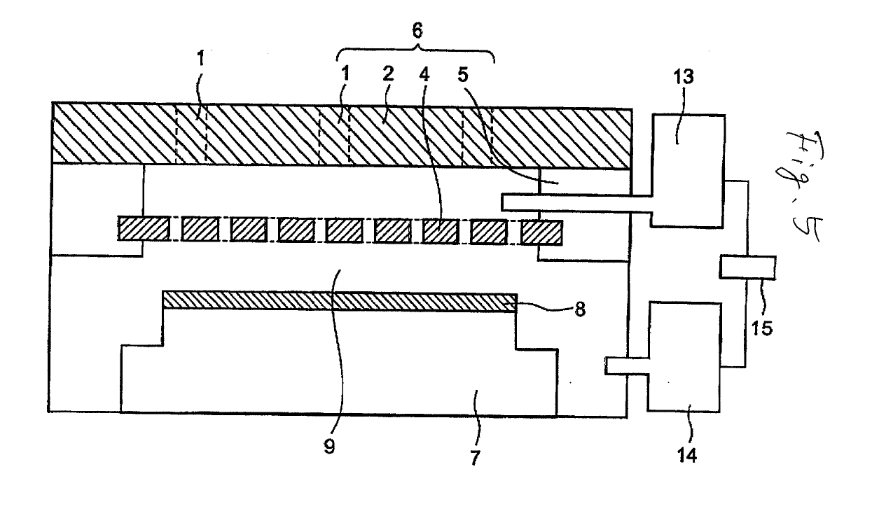

FIG. 5 is a diagram showing a third embodiment. In the third embodiment, the plasma detector 11 employed in the first embodiment is replaced by a first pressure gauge 13. Further, a second pressure gauge 14 is placed in an etching-processing chamber 9.

A pressure measuring device has heretofore been not installed on the backside (on the cooling plate 2 side in FIG. 5) of the gas-introducing plate 4. In the present embodiment, the first pressure gauge 13 is provided on the backside thereof. Further, the second pressure gauge 14 is placed even in the etching-processing chamber 9. These first and second pressure gauges may be ones now on the market. It is however desirable that a high-accuracy pressure gauge capable of capturing even a slight fluctuation in pressure is used. The first and second pressure gauges are not intended only for their single detection of pressure fluctuations. Detecting means 15 capable of detecting the difference in pressure between the respective pressure gauges is provided.

While normal etching is being carried out in the etching-processing chamber 9, no plasma enters the backside of the gas-introducing plate 4. However, when the gas-introducing plate 4 is used up, gas holes 3 defined in the gas-introducing plate 4 increase in size. When the size of each gas hole 3 exceeds a predetermined size, the plasma enters the back of the gas-introducing plate 4. In doing so, the difference between pressure on the backside of the gas-introducing plate and pressure lying within the etching-processing chamber 9 becomes small.

Even when trouble occurs in the etching-processing chamber and hence the state of the plasma becomes unstable, the plasma is generated on the backside of the gas-introducing plate. As the occurrence of defective conditions, may be mentioned a case in which a fluctuation in pressure due to leaks occurs, a case in which the amount of supply of high-frequency power varies, etc. In a manner similar to the above even in these cases, the difference between the pressure on the backside of the gas-introducing plate 4 and the pressure within the etching-processing chamber 9 becomes small.

While the etching is being carried out in a normal state, the difference between the pressure on the backside (cooling plate 2 side) of the gas-introducing plate 4 and the pressure in the etching-processing chamber 9 increases. This reason is as follows: The pressure is high because gas is always supplied from gas supply holes defined in the cooling plate 2 in plural form on the backside of the gas-introducing plate 4. On the other hand, since the gas reacted by etching is always exhausted from the etching-processing chamber 9, the pressure is low. When the plasma enters the backside of the gas-introducing plate 4 and is generated on the backside thereof, the difference in pressure referred to above changes from its large state to its small state. This change is detected by the first and second pressure gauges and the detecting means 15. When the difference in pressure is lower than a set pressure difference, the etching apparatus is deactivated.

Owing to the provision of the first and second pressure gauges on the backside of the gas-introducing plate 4 and within the etching-processing chamber 9 respectively and the provision of the difference-in-pressure detecting means 15 as described above, the difference between the pressure on the backside of the gas-introducing plate 4 and the pressure lying within the etching-processing chamber 9 is detected with extremely high accuracy. Thus, highly-sensitive detection can be achieved as compared with the second embodiment. The etching apparatus is deactivated simultaneously with the time when the defective conditions are detected. The wasted gas-introducing plate 4 is reliably replaced by another.

Accordingly, a wafer 8 can be prevented form being abnormally etched due to overusing of the gas-introducing plate 4. Since the gas-introducing plate 4 is used to its limitation, a reduction in cost thereof can be achieved.

Further, since the second pressure gauge 14 is provided even in the etching-processing chamber in the present embodiment, a fluctuation in pressure in the etching-processing chamber can be detected. It is possible to detect not only defective conditions caused by the gas-introducing plate but also etching trouble in the etching-processing chamber. This etching trouble includes, for example, a case in which the state of plasma becomes non-uniform, a case in which a wafer cooling gas leaks within the etching-processing chamber 9, etc.

While the present invention has been described with reference to the illustrative embodiments, this description is not intended to be construed in a limiting sense. Various modifications of the illustrative embodiments, as well as other embodiments of the invention, will be apparent to those skilled in the art on reference to this description. It is therefore contemplated that the appended claims will cover any such modifications or embodiments as fall within the true scope of the invention.

What is claimed is:

1. An apparatus for manufacturing a semiconductor device, comprising:
plasma detecting means provided inside an upper electrode for supplying gas, of a parallel-plate type dry etching apparatus.

2. The apparatus according to claim 1, wherein said upper electrode comprises a cooling plate having a plurality of gas supply holes for supplying the gas, a gas-introducing plate having gas holes for introducing the gas into a semiconductor wafer, a jig for fixing said gas-introducing plate to said cooling plate, and a sensor for detecting plasma, which is provided between said gas-introducing plate and said cooling plate.

3. An apparatus for manufacturing a semiconductor device, comprising:
pressure detecting means provided inside an upper electrode for supplying gas, of a parallel-plate type dry etching apparatus.

4. The apparatus according to claim 3, wherein said upper electrode comprises a cooling plate having a plurality of gas supply holes for supplying the gas, a gas-introducing plate having gas holes for introducing the gas into a semiconductor wafer, a jig for fixing said gas-introducing plate to said cooling plate, and means for detecting pressure, which is provided between said gas-introducing plate and said cooling plate.

5. An apparatus for manufacturing a semiconductor device, comprising:
first pressure detecting means provided inside an upper electrode for supplying gas, of a parallel-plate type dry etching apparatus; and
second pressure detecting means provided within an etching-processing chamber in which a wafer is placed.

6. The apparatus according to claim 5, further including means for connecting said first pressure detecting means and said second pressure detecting means and detecting the difference between pressure detected by said first pressure detecting means and pressure detected by said second pressure detecting means.

7. The apparatus according to claim 5, wherein said upper electrode comprises a cooling plate having a plurality of gas supply holes for supplying the gas, a gas-introducing plate having gas holes for introducing the gas into a semiconductor wafer, a jig for fixing said gas-introducing plate to said cooling plate, and first pressure detecting means for detecting pressure, which is provided between said gas-introducing plate and said cooling plate, and wherein second pressure detecting means is provided within the etching-processing chamber in which the wafer is placed.
